(19) United States
(12) Patent Application Publication
(10) Pub. No.: US 2026/0301626 A1
(43) Pub. Date: Oct. 1, 2026

(54) SHIFT REGISTER, SCANNING DRIVER CIRCUIT AND DISPLAY PANEL

(71) Applicant: BOE TECHNOLOGY GROUP CO., LTD., Beijing (CN)

(72) Inventors: Guangliang Shang, Beijing (CN); Yinglong Huang, Beijing (CN); Gen Li, Beijing (CN)

(73) Assignee: BOE TECHNOLOGY GROUP CO., LTD., Beijing (CN)

(21) Appl. No.: 19/480,084

(22) PCT Filed: Mar. 26, 2025
(86) PCT No.: PCT/CN2025/085129

§ 371 Date: Oct. 30, 2025

(30) Foreign Application Priority Data
Apr. 26, 2024 (CN) 202410513454.2

(51) Int. Cl. G09G 3/20; G11C 19/28

(52) U.S. Cl. CPC G09G 3/20; G11C 19/28; G09G 2310/0286

(57) ABSTRACT

The present disclosure provide a shift register, a scanning driver circuit and a display panel. The shift register includes: an input circuit, electrically connected to an input terminal and a pull-up node, and configured to write a signal from the input terminal to the pull-up node when in a conductive state; a first output circuit, electrically connected to the pull-up node, a first clock signal terminal and a first output terminal, and configured to write a signal from the first clock signal terminal to the first output terminal under control of a signal at the pull-up node; and a second output circuit, electrically connected to the pull-up node, a second clock signal terminal and a second output terminal, and configured to write a signal from the second clock signal terminal to the second output terminal under the control of the signal at the pull-up node.

### CROSS-REFERENCE TO RELATED APPLICATION

This application claims the priority of the Chinese Patent application filed on Apr. 26, 2024 before the CNIPA, China National Intellectual Property Administration with the application number of 202410513454.2, and the title of “SHIFT REGISTER, SCANNING DRIVER CIRCUIT AND DISPLAY PANEL”, which is incorporated herein in its entirety by reference.

### TECHNICAL FIELD

The present disclosure relates to the technical field of display and more particularly, to a shift register, a scanning driver circuit and a display panel.

### BACKGROUND

In related art, the border of the display panel is wide, which affect user experience of customers.

### SUMMARY

Embodiments of the present disclosure provides a shift register, a scanning driver circuit and a display panel.

On one hand, a shift register is provided, which includes:
an input circuit, wherein the input circuit is electrically connected to an input terminal and a pull-up node, and the input circuit is configured to write a signal from the input terminal to the pull-up node;
a first output circuit, wherein the first output circuit is electrically connected to the pull-up node, a first clock signal terminal and a first output terminal, and the first output circuit is configured to write a signal from the first clock signal terminal to the first output terminal under control of a signal at the pull-up node;
a second output circuit, wherein the second output circuit is electrically connected to the pull-up node, a second clock signal terminal and a second output terminal, and the second output circuit is configured to write a signal from the second clock signal terminal to the second output terminal under the control of the signal at the pull-up node.

In some embodiments, the shift register further includes:
a first isolation circuit, wherein the first isolation circuit is electrically connected between the pull-up node and the first output circuit, the first isolation circuit is electrically connected to a first isolation control terminal, and the first isolation circuit is configured to disconnect an electrical connection between the pull-up node and the first output circuit under control of a signal from the first isolation control terminal.

In some embodiments, the shift register further includes:
a second isolation circuit, wherein the second isolation circuit is electrically connected between the pull-up node and the second output circuit, the second isolation circuit is electrically connected to a second isolation control terminal, and the second isolation circuit is configured to disconnect an electrical connection between the pull-up node and the second output circuit under control of a signal from the second isolation control terminal.

In some embodiments, the first isolation control terminal is electrically connected to the second isolation control terminal.

In some embodiments, the first isolation circuit is configured to disconnect the electrical connection between the pull-up node and the first output circuit when the first output terminal is at a high-level signal; and/or, the second isolation circuit is configured to disconnect the electrical connection between the pull-up node and the second output circuit when the second output terminal is at the high-level signal.

In some embodiments, the first isolation circuit includes a first isolation transistor, a first electrode of the first isolation transistor is electrically connected to the pull-up node, a second electrode of the first isolation transistor is electrically connected to the first output circuit, and a gate of the first isolation transistor is electrically connected to the first isolation control terminal; and/or, the second isolation circuit includes a second isolation transistor, a first electrode of the second isolation transistor is electrically connected to the pull-up node, a second electrode of the second isolation transistor is electrically connected to the second output circuit, and a gate of the second isolation transistor is electrically connected to the second isolation control terminal.

In some embodiments, the shift register further includes:
a cascade circuit, wherein the cascade circuit is electrically connected to a cascade signal terminal, the pull-up node and a cascade output terminal, and the cascade circuit is configured to write a signal from the cascade signal terminal to the cascade output terminal under the control of the signal at the pull-up node.

In some embodiments, the shift register further includes:
a third isolation circuit, wherein the third isolation circuit is electrically connected between the pull-up node and the cascade circuit, the third isolation circuit is electrically connected to a third isolation control terminal, and the third isolation circuit is configured to disconnect an electrical connection between the pull-up node and the cascade circuit under control of a signal from the third isolation control terminal.

In some embodiments, the third isolation control terminal is electrically connected to a first isolation control terminal and a second isolation control terminal.

In some embodiments, the third isolation circuit includes a third isolation transistor, a first electrode of the third isolation transistor is electrically connected to the pull-up node, a second electrode of the third isolation transistor is electrically connected to the cascade circuit, and a gate of the third isolation transistor is electrically connected to the third isolation control terminal.

In some embodiments, at least a portion of transistors in the shift register are double gate structures.

In some embodiments, the input circuit includes a first input transistor and a second input transistor, a first electrode of the first input transistor is electrically connected to the input terminal, a second electrode of the first input transistor is electrically connected to a first electrode of the second input transistor, a second electrode of the second input transistor is electrically connected to the pull-up node, and gates of the first input transistor and the second input transistor is electrically connected to the input terminal;
the shift register further includes a leakage-prevention circuit, the leakage-prevention circuit is electrically connected to a first voltage terminal, a leakage-prevention control terminal and the second electrode of the first input transistor, and the leakage-prevention circuit is configured to write a signal from the first voltage terminal to the second electrode of the first input transistor under control of a signal from the leakage-prevention control terminal.

In some embodiments, the shift register further includes a reset circuit, the reset circuit is electrically connected to a first pull-down node, a second pull-down node, the first output terminal, the second output terminal and a second voltage terminal, and the reset circuit is configured to write a signal from the second voltage terminal to the first output terminal or the second output terminal under control of a signal at the first pull-down node or the second pull-down node.

On another hand, a scanning driver circuit is provided, which includes a plurality of shift registers as described above, and the plurality of shift registers are cascaded.

In some embodiments, the plurality of shift registers include a first shift register and a second shift register, the first shift register and the second shift register are cascaded, a first pull-down node of the first shift register is electrically connected to a first pull-down node of the second shift register, and a second pull-down node of the first shift register is electrically connected to a second pull-down node of the second shift register; and the first shift register further includes a first noise-reduction circuit, the first noise-reduction circuit is electrically connected to the first pull-down node, and the second shift register further includes a second noise-reduction circuit, the second noise-reduction circuit is electrically connected to the second pull-down node.

On yet another hand, a display panel is provided, which includes the above shift register or the above scanning driver circuit.

The embodiments of the present disclosure provides the shift register, the scanning driver circuit and the display panel. The shift register include both the first output circuit and the second output circuit. The first output circuit is electrically connected to one sub-pixel row through the first output terminal, and the second output circuit is electrically connected to another sub-pixel row through the second output terminal. That is, one shift register can provide scanning signals to multiple sub-pixel rows. With the number of sub-pixel rows in the display panel remaining unchanged, the number of shift registers in the scanning driver circuit can be reduced, thereby reducing the area of non-active areas in the display panel and meeting the demand for narrow borders of the display panel.

### BRIEF DESCRIPTION OF THE DRAWINGS

In order to more clearly illustrate the technical solution in the embodiments of the present disclosure or in the prior art, a brief introduction will be given to the accompanying drawings required to be used in the embodiments and the prior art. It is obvious that the accompanying drawings described below are only some embodiments of the present disclosure. For those skilled in the art, other drawings may be obtained based on these drawings without creative work.

FIG. 1 is an application scenario diagram of a display panel according to an embodiment of the present disclosure;

FIG. 2 is a schematic structural diagram of a display panel according to an embodiment of the present disclosure;

FIG. 3 is a block diagram of a partial structure of a shift register according to an embodiment of the present disclosure;

FIG. 4 is a schematic diagram of a partial structure of a shift register according to an embodiment of the present disclosure;

FIG. 5 is a timing signal diagram of a shift register according to an embodiment of the present disclosure;

FIG. 6 is a cascaded relationship diagram of two adjacent shift registers in a display panel according to an embodiment of the present disclosure;

FIG. 7 is a block diagram of a partial structure of another shift register according to an embodiment of the present disclosure;

FIG. 8 is a schematic diagram of a partial structure of another shift register according to an embodiment of the present disclosure;

FIG. 9 is a structural block diagram of another shift register according to an embodiment of the present disclosure;

FIG. 10 is a circuit schematic diagram of another shift register according to an embodiment of the present disclosure;

FIG. 11 is a signal timing diagram of the shift register shown in FIG. 10;

FIG. 12 is a block diagram of a partial structure of another shift register according to an embodiment of the present disclosure;

FIG. 13 is a schematic diagram of a partial structure of another shift register according to an embodiment of the present disclosure;

FIG. 14 is a schematic structural diagram of another shift register according to an embodiment of the present disclosure;

FIG. 15 is a schematic diagram of a partial structure of another shift register according to an embodiment of the present disclosure;

FIG. 16 is a circuit schematic diagram of another shift register according to an embodiment of the present disclosure;

FIG. 17 is a timing signal diagram of the shift register shown in FIG. 16;

FIG. 18 is a circuit schematic diagram of a shift register according to an embodiment of the present disclosure;

FIG. 19 is a timing signal diagram of the shift register shown in FIG. 16;

FIG. 20 is a circuit schematic diagram of another shift register according to an embodiment of the present disclosure;

FIG. 21 is a circuit schematic diagram of another shift register according to an embodiment of the present disclosure;

FIG. 22 is a circuit schematic diagram of another shift register according to an embodiment of the present disclosure;

FIG. 23 is a circuit schematic diagram of another shift register according to an embodiment of the present disclosure;

FIG. 24 is a circuit schematic diagram of a first shift register according to an embodiment of the present disclosure; and

FIG. 25 is a circuit schematic diagram of a second shift register according to an embodiment of the present disclosure.

### DETAILED DESCRIPTION

Below, a clear and complete description of the technical solution in the embodiment of the present disclosure will be provided in conjunction with the accompanying drawings of the embodiment of the present disclosure. Obviously, the described embodiments are only a part of the embodiments of the present disclosure, not all of them. Based on the embodiments of the present disclosure, all other embodiments obtained by persons skilled in the art without creative work are within the scope of protection of the present disclosure.

In the embodiments of the present disclosure, the use of words such as “first”, “second”, “third”, “fourth” to distinguish similar or identical items with similar functions and effects is only for the purpose of clearly describing the technical solution of the embodiments of the present disclosure, and cannot be understood as indicating or implying relative importance or implying the number of technical features indicated.

In the embodiments of the present disclosure, the meaning of “plurality of” refers to two or more, and the meaning of “at least one” refers to one or more, unless otherwise specified.

In the embodiments of the present disclosure, the terms “up”, “down”, etc. indicate orientation or positional relationships based on the orientation or positional relationships shown in the accompanying drawings. This is only for the convenience of describing and simplifying the description of the present disclosure, and does not indicate or imply that the device or element referred to must have a specific orientation, be constructed and operated in a specific orientation, and therefore cannot be understood as a limitation of the present disclosure.

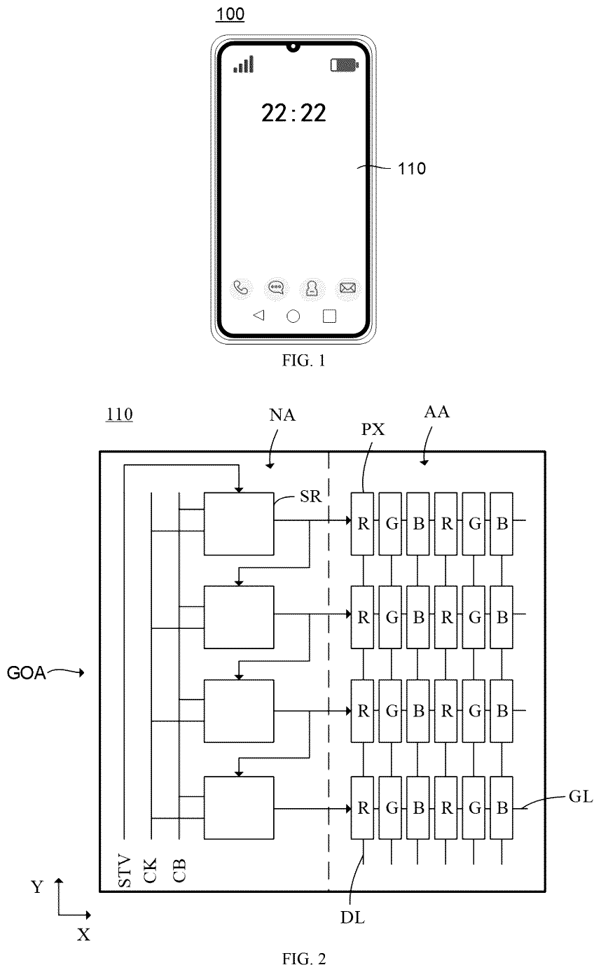

The embodiment of the present disclosure provides a display panel that can be applied to various devices and equipment with display functions for displaying graphics. For example, the display panels can be applied to mobile phones, wireless devices, personal data assistants (PDAs), handheld or portable computers, GPS receivers/navigators, cameras, MP4 video players, cameras, game consoles, watches, clocks, calculators, television monitors, flat panel displays, computer monitors, car displays (such as odometer displays, etc.), navigators, cockpit controllers and/or displays, camera view displays (such as displays for rearview cameras in vehicles), electronic photos, electronic billboards or signs, projectors, building structures, packaging and aesthetic structures (such as displays for images of a piece of jewelry), etc. FIG. 1 shows an application scenario diagram of a display panel 110 according to an embodiment of the present disclosure. FIG. 1 illustrates the application of the display panel 110 to a mobile phone as an example.

The display panel 110 may be a liquid crystal display (LCD) panel. When the display panel 110 is the liquid crystal display panel, the display panel 110 can be a horizontal electric field type liquid crystal display panel or a vertical electric field type liquid crystal display panel. When the display panel 110 is the horizontal electric field type liquid crystal display panel, the display panel 110 may be an in-plane switching (IPS) liquid crystal display panel or an advanced super dimension switch (ADS) liquid crystal display panel.

The display panel 110 can also be an electroluminescent display panel or a photoluminescent display panel. When the display panel 110 is the electroluminescent display panel, the electroluminescent display panel can be an organic light-emitting diode (OLED) display panel or a quantum dot light emitting diode (QLED) display panel. When the display panel 110 is the photoluminescence display panel, the photoluminescence display panel can be a quantum dot photoluminescence display panel. Some embodiments of the present disclosure take the display panel 110 being an organic light-emitting diode (OLED) display panel as an example.

FIG. 2 is a schematic structural diagram of a display panel provided in the embodiment of the present disclosure. As shown in FIG. 2, the display panel is provided with a scanning driver circuit GOA, a plurality of gate lines GL, a plurality of data lines DL, and a plurality of sub-pixels PX.

The display panel may have an active area AA and a non-active area NA electrically connected to the active area AA. The non-active area NA may be located on one, two, or three sides of the active area AA, or may be arranged around the active area AA.

The plurality of sub-pixels PX, the plurality of gate lines GL, and the plurality of data lines DL can be located within the active area AA, and the scanning driver circuit GOA can be located within the non-active area NA. In practical applications, in order to reduce the width of the non-active area NA of the display panel 110, some structures of the scanning driver circuit GOA can also be located within the active area AA.

For example, the plurality of sub-pixels PX are arranged in an array. For example, after arranging the plurality of sub-pixels PX in an array, the plurality of sub-pixel rows and columns are formed. The plurality of sub-pixels PX within one sub-pixel row are arranged along a first direction X, and the plurality of sub-pixels PX within one sub-pixel column are arranged along a second direction Y.

Among them, the first direction X and the second direction Y intersect with each other. The angle between the first direction X and the second direction Y can be selected and set according to actual needs. For example, the angle between the first direction X and the second direction Y can be 85°, 88°, 90°, 92°, or 95°, etc.

The sub-pixel PX may include a pixel driving circuit PI and a light-emitting device P2 electrically connected to the pixel driving circuit PI. When the display panel 110 operates, the light-emitting device P2 can emit light under the driving of the pixel driving circuit P1.

The structure of the pixel driving circuit PI can have multiple types and can be flexibly selected according to actual needs. For example, the structure of the pixel driving circuit PI can be “3T1C”, “6T1C”, “7T1C”, “6T2C” or “7T2C”. Among them, “T” represents the transistor, the number before “T” represents the number of the transistors, “C” represents the storage capacitor, and the number before “C” represents the number of the storage capacitors.

For example, one gate line GL can be electrically connected to a plurality of pixel driving circuits P1 in one sub-pixel row, and one data line DL can be electrically connected to a plurality of pixel driving circuits P1 in one sub-pixel column.

Continuing to refer to FIG. 2, the scanning driver circuit GOA is electrically connected to the end of the gate line GL. It should be noted that in FIG. 2, only the scanning driver circuit GOA being connected to the left end of the gate line GL is taken as an example. The scanning driver circuit GOA can also be connected to the right end of the gate line GL, or both the left and right ends of the gate line GL can be electrically connected to the scanning driver circuit GOA.

The scanning drive circuit GOA includes a plurality of cascaded shift registers SR, the shift register SR includes an output terminal. The output terminal of the shift register SR is electrically connected to the gate line GL. When the scanning driver circuit GOA operates, the output terminals of the plurality of cascaded shift registers SR output scanning signals to the pixel driving circuit PI step by step through the gate line GL.

In related art, one shift register only includes one output terminal, the output terminal is connected to the gate line. As the pixel density of the display panel increases, the number of sub-pixel rows in the display panel also increases. Correspondingly, the number of shift registers in the scanning driver circuit also increases, resulting in a larger area of the non-active area of the display panel, which cannot meet the user's demand for narrow borders.

In view of this, the embodiment of the present disclosure provides a shift register including a plurality of output terminals, such that one shift register can provide scanning signals to a plurality of sub-pixels, reducing the number of shift registers in the scanning driver circuit, and thus reducing the area of the non-active area NA.

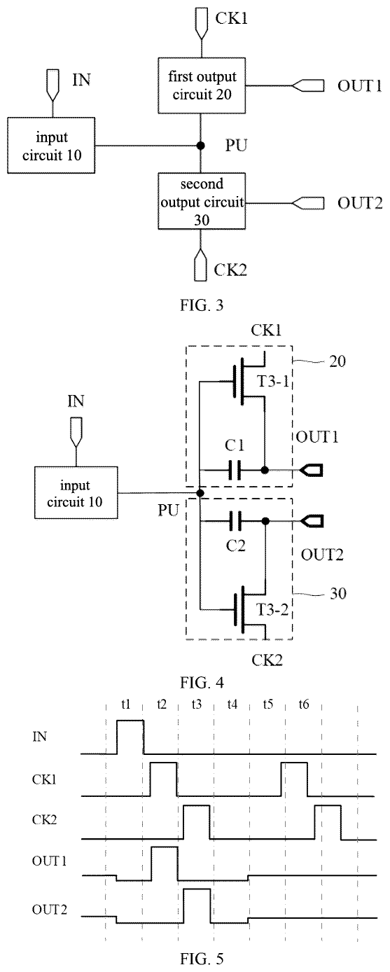

FIG. 3 is a block diagram of a partial structure of a shift register according to an embodiment of the present disclosure. As shown in FIG. 3, the shift register includes an input circuit 10, a first output circuit 20 and a second output circuit 30. The input circuit 10 is electrically connected to an input terminal IN and a pull-up node PU, the first output circuit 20 is electrically connected to the pull-up node PU, a first clock signal terminal CK1 and a first output terminal OUT1, the second output circuit 30 is electrically connected to the pull-up node PU, a second clock signal terminal CK2 and a second output terminal OUT2.

The input terminal IN can be electrically connected to a starting signal line or to the output terminals of other shift registers. For example, when the shift register is located at a starting position, the input terminal IN of this shift register is electrically connected to the starting signal line. When the shift register is located at a non-starting position, the input terminal IN of this shift register is electrically connected to one of the output terminals of the previous-stage shift register.

Among them, the shift register located at the starting position can be the topmost shift register in FIG. 2. The previous-stage shift register of a shift register can be a shift register located above and adjacent to this shift register. For example, the shift register located at the starting position in FIG. 2 is the previous-stage shift register of the second one of the shift registers.

The pull-up node PU is a virtual node that represents the intersection of the electrical connections of the input circuit 10, the first output circuit 20, and the second output circuit 30.

The first output terminal OUT1 is electrically connected to one of the gate lines GL, the second output terminal OUT2 is electrically connected to another gate line GL, and the two gate lines GL are respectively electrically connected to different sub-pixel rows. For example, the plurality of sub-pixel rows within the display panel 110 include a first sub-pixel row and a second sub-pixel row that are adjacent, the first output terminal OUT1 is electrically connected to the first sub-pixel row, and the second output terminal OUT2 is electrically connected to the second sub-pixel row.

The scanning driver circuit also includes a first clock signal line and a second clock signal line. The first clock signal line is electrically connected to the first clock signal terminal CK1, and the second clock signal line is electrically connected to the second clock signal terminal CK2. Among them, the signals in the first clock signal line and the second clock signal line may be different.

The working state of the input circuit 10 includes a conductive state. In the conductive state, the input circuit 10 is configured to write the signal from the input terminal IN to the pull-up node PU. For example, when the signal from the input terminal IN is a high-level signal, the input circuit 10 is in the conductive state and writes the high-level signal from the input terminal IN to the pull-up node PU.

The first output circuit 20 is configured to write a signal from the first clock signal terminal CK1 to the first output terminal OUT1 under control of a signal at the pull-up node PU. For example, when the signal at the pull-up node PU is the high-level signal, the first output circuit 20 writes the signal from the first clock signal terminal CK1 into the first output terminal OUT1.

The second output circuit 30 is configured to write the signal from the second clock signal terminal CK2 to the second output terminal OUT2 under the control of the signal at the pull-up node PU. For example, when the signal at the pull-up node PU is the high-level signal, the second output circuit 30 writes the signal from the second clock signal terminal CK2 to the second output terminal OUT2.

FIG. 4 is a schematic diagram of a partial structure of a shift register according to an embodiment of the present disclosure. As shown in FIG. 4, the first output circuit 20 includes a first output transistor T3-1 and a first capacitor C1. The first electrode of the first output transistor T3-1 is electrically connected to the first clock signal terminal CK1, the second electrode of the first output transistor T3-1 is electrically connected to the first output terminal OUT1, the gate of the first output transistor T3-1 is electrically connected to the pull-up node PU, the first electrode plate of the first capacitor C1 is electrically connected to the pull-up node PU, and the second electrode plate of the first capacitor C1 is electrically connected to the first output terminal OUT1. The second output circuit 30 includes a second output transistor T3-2 and a second capacitor C2. The first electrode of the second output transistor T3-2 is electrically connected to the second clock signal terminal CK2, the second electrode of the second output transistor T3-2 is electrically connected to the second output terminal OUT2, the gate of the second output transistor T3-2 is electrically connected to the pull-up node PU, the first electrode plate of the second capacitor C2 is electrically connected to the pull-up node PU, and the second electrode plate of the first capacitor C1 is electrically connected to the second output terminal OUT2.

The transistor used in the embodiment of the present disclosure can be a thin film transistor (TFT), a field-effect transistor (FET), or other devices with the same characteristic. Since the source and the drain of the transistor used are symmetrical, there is no difference in the source and the drain thereof. In this embodiment of the present disclosure, to distinguish between the source and the drain of the transistor, one electrode is referred to as the first electrode, and the other electrode is referred to as the second electrode. In addition, the transistors can be classified into a N-type transistor and a P-type transistor according to characteristics of the transistors. In the following embodiments, the N-type transistor is used for explanation. When the high-level signal is input into the gate, the source and the drain are conductive, while the P-type transistor behaves in the opposite way. It can be seen that using the P-type transistors for implementation is something that persons skilled in the art can easily come up with without creative work, and therefore falls within the scope of protection of the embodiments of the present disclosure.

FIG. 5 is a timing signal diagram of a shift register according to an embodiment of the present disclosure. The working process of the shift register shown in FIG. 4 will be illustrated with reference to FIG. 5. During the time period t1, the input terminal IN is at the high-level signal, the input circuit 10 is in the conductive state, and the input circuit 10 writes the high-level signal from the input terminal IN to the pull-up node PU. The first output circuit 20, under the control of the high-level signal at the pull-up node PU, writes a low-level signal from the first clock signal terminal CK1 to the first output terminal OUT1. The second output circuit 30, under the control of the high-level signal at the pull-up node PU, writes the low-level signal from the second clock signal terminal CK2 to the second output terminal OUT2. During the time period t2, the input terminal IN is at the low-level signal, and the input terminal IN is disconnected from the pull-up node PU, the pull-up node PU maintains the high-level signal under the action of the first capacitor C1 and the second capacitor C2. The first output circuit 20 writes the high-level signal from the first clock signal terminal CK1 to the first output terminal OUT1 under the control of the high-level signal at the pull-up node PU, and the second output circuit 30 writes the low-level signal from the second clock signal terminal CK2 to the second output terminal OUT2 under the control of the high-level signal at the pull-up node PU. During the time period t3, the input terminal IN is at the low-level signal, and the input terminal IN is disconnected from the pull-up node PU, the pull-up node PU maintains the high-level signal under the action of the first capacitor C1 and the second capacitor C2. The first output circuit 20 writes the low-level signal from the first clock signal terminal CK1 to the first output terminal OUT1 under the control of the high-level signal at the pull-up node PU, and the second output circuit 30 writes the high-level signal of the second clock signal terminal CK2 to the second output terminal OUT2 under the control of the high-level signal at the pull-up node PU. That is, the first output terminal OUT1 and the second output terminal OUT2 can output high-level scanning signals step by step.

The shift register provided in this embodiment of the present disclosure includes both the first output circuit 20 and the second output circuit 30. The first output circuit 20 is electrically connected to one of the sub-pixel rows through the first output terminal OUT1, and the second output circuit 30 is electrically connected to another sub-pixel row through the second output terminal OUT2. That is, one shift register can provide scanning signals to a plurality of sub-pixel rows. With the number of the sub-pixel rows in the display panel unchanged, the number of the shift registers in the scanning driver circuit can be reduced, thereby reducing the area of the non-active areas in the display panel and meeting the demand for narrow borders of the display panel.

It should be noted that the shift register of this embodiment of the present disclosure includes a plurality of output circuits, and the number of the output circuits can be two, three, four, five, etc. For the sake of convenience in description, this embodiment of the present disclosure only takes the shift register including the first output circuit 20 and the second output circuit 30 as an example. In practical applications, the shift register may also include a third output circuit, a fourth output circuit, a fifth output circuit, etc. For example, the third output circuit is electrically connected to the pull-up node PU, the third clock signal terminal, and the third output terminal. The third output circuit is configured to write the signal from the third clock signal terminal to the third output terminal under the control of the signal at the pull-up node PU. The fourth output circuit, the fifth output circuit, and so on, will not be elaborated here.

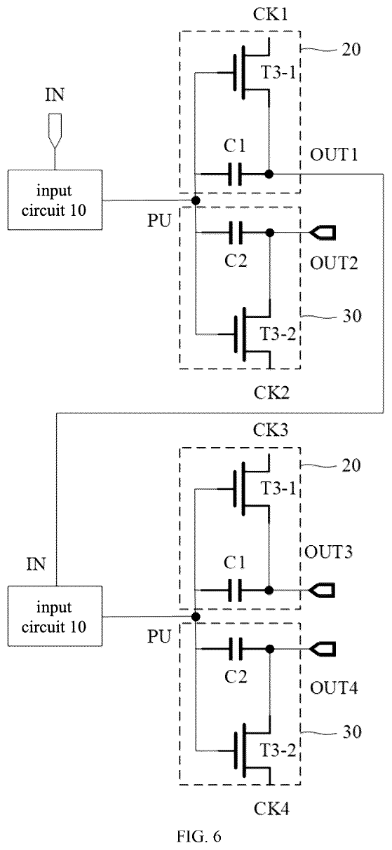

FIG. 6 is a cascaded relationship diagram of two adjacent shift registers in a display panel according to an embodiment of the present disclosure. For the convenience of illustration, the first clock signal terminal of the next-stage shift register is represented by CK3, the second clock signal terminal of the next-stage shift register is represented by CK4, the first output terminal of the next-stage shift register is represented by OUT3, and the second output terminal of the next-stage shift register is represented by OUT4.

As shown in FIG. 6, the first output terminal OUT1 of the previous-stage shift register is electrically connected to the input terminal IN of the next-stage shift register. The scanning driver circuit also includes a first clock signal line CLK1, a second clock signal line CLK2, a third clock signal line CLK3, and a fourth clock signal line CLK4. The first clock signal line CLK1 is electrically connected to the first clock signal terminal CK1 of the previous-stage shift register, the second clock signal line CLK2 is electrically connected to the second clock signal terminal CK2 of the previous-stage shift register, the third clock signal line CLK3 is electrically connected to the first clock signal terminal CK3 of the next-stage shift register, and the fourth clock signal line CLK4 is electrically connected to the second clock signal terminal CK4 of the next-stage shift register.

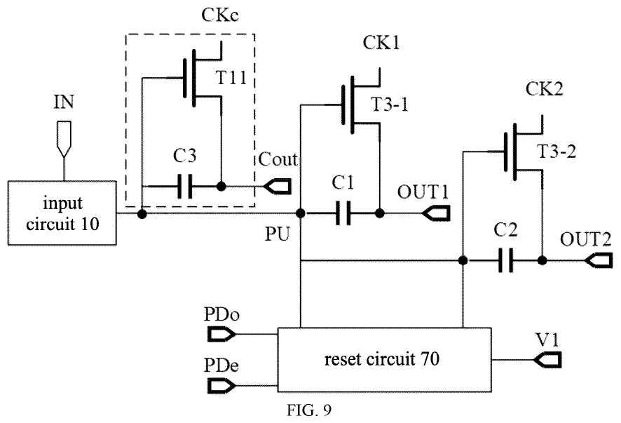

FIG. 9 is a structural block diagram of another shift register according to an embodiment of the present disclosure. As shown in FIG. 9, the shift register may also include a reset circuit 70, the reset circuit 70 is electrically connected to the first pull-down node PDo, the second pull-down node PDe, the first output terminal OUT1, the second output terminal OUT2, and the second voltage terminal V2, respectively.

The reset circuit 70 is configured to write a signal from the second voltage terminal V2 to the first output terminal OUT1 or the second output terminal OUT2 under control of a signal at the first pull-down node PDo or the second pull-down node PDe. For example, when the second voltage terminal V2 is electrically connected to VGL and the signal at the first pull-down node PDo or the second pull-down node PDe is the high-level signal, the reset circuit 70 writes the low-level signal from the second voltage terminal V2 to the first output terminal OUT1 or the second output terminal OUT2.

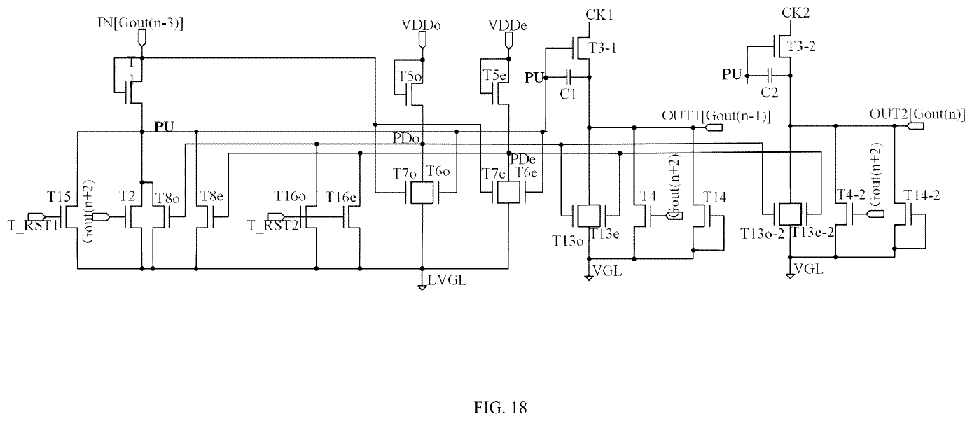

FIG. 18 is a circuit schematic diagram of a shift register according to an embodiment of the present disclosure. For example, as shown in FIG. 18, the input circuit 10 includes a first transistor T1, the first electrode and the gate of the first transistor TI are both electrically connected to the input terminal IN, and the second electrode of the first transistor TI is electrically connected to the pull-up node PU.

Among them, the level of LVGL is lower than that of VGL, which can reduce a situation where TFT Vth is negative, ensure that there is no leakage when the output terminal outputs a high level, and also accelerate the discharge process of the output terminal. Because the discharge path of this structure is CK1/CK2, and the low level of CK1/CK2 is LVGL, it can make the output reset to VGL faster. T_RST1 and T_RST2 are the total reset signals, usually at the low level, used to reset status and output of the shift register. T_RST1 is used to reset all pull-up nodes PU during the frame blank time, while T_RST2 is used to reset all pull-down nodes (PDo, Pde) during turning on/off (power on/off), to initialize the status of the shift register and improve display reliability. VDDo/VDDe is a power supply with opposite high and low levels, and the alternating period can be from 2 frames to several seconds or longer. The switching time is generally set at the frame blank time. The voltage can be a constant VGH voltage or an adjustable voltage that varies with the working time of the shift register. The transistor T14 can be placed close to or far from the output of the shift register to prevent damage to the structure caused by electrostatic discharge (Electro-Static Discharge, ESD).

The number of the transistors in the shift register shown in FIG. 18 is relatively small, so the area of the non-active area NA in the display panel can be reduced, thereby reducing the width of the bezel of the display panel.

Due to the fact that the first output terminal OUT1 of the previous-stage shift register is not only electrically connected to the input terminal IN of the next-stage shift register, but also electrically connected to the pixel drive circuit within one sub-pixel row, the load on the first output terminal OUT1 is relatively large, resulting in signal attenuation at the input terminal IN of the next-stage shift register, and the further down the shift register is, the more severe the signal attenuation.

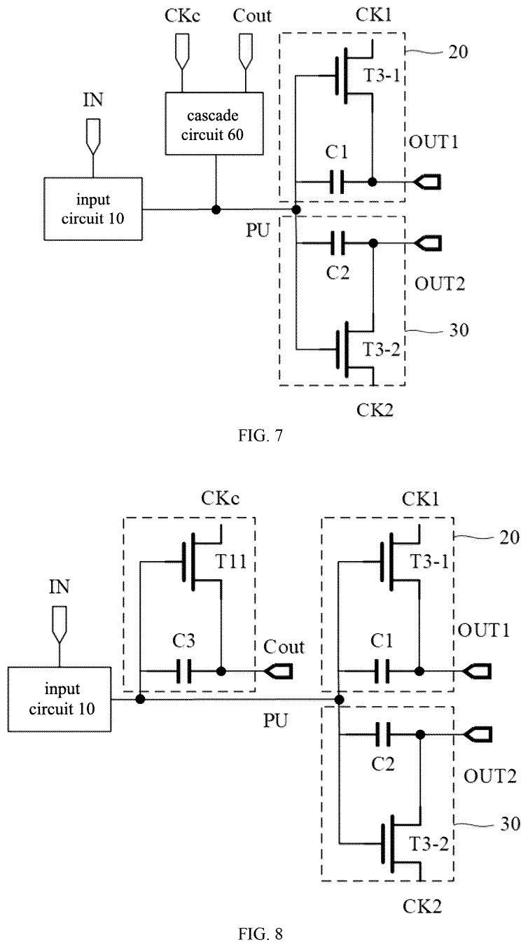

FIG. 7 is a block diagram of a partial structure of another shift register according to an embodiment of the present disclosure. As shown in FIG. 7, the shift register further includes a cascade circuit 60, the cascade circuit 60 is electrically connected to a cascade signal terminal CKc, the pull-up node PU and a cascade output terminal Cout.

The cascade circuit 60 is configured to write a signal from the cascade signal terminal CKc to the cascade output terminal Cout under the control of the signal at the pull-up node PU. For example, when the cascade signal terminal CKc is at the high-level signal, the cascade circuit 60 writes the high-level signal from the cascade signal terminal CKc into the cascade output terminal Cout.

When the plurality of shift registers are cascaded, the cascade output terminal Cout of the previous-stage shift register is electrically connected to the input terminal IN of the next-stage shift register. Since the cascade output terminal Cout is not electrically connected to the pixel driving circuit within the sub-pixel row, the load on the cascade output terminal Cout is relatively small, and the signal input to the input terminal IN of the next-stage shift register will not attenuate or attenuate slightly, improving the display uniformity of the display panel. Moreover, the signal of the cascade output terminal Cout in each shift register is written from the cascade signal terminal CKc, so there will be no accumulated attenuation, which improves the display uniformity of the display panel.

FIG. 8 is a schematic diagram of the partial structure of another shift register according to an embodiment of the present disclosure. As shown in FIG. 8, the cascade circuit 60 includes an eleventh transistor T11 and a third capacitor C3, the first electrode of the eleventh transistor T11 is electrically connected to the cascade signal terminal CKc, the second electrode of the eleventh transistor T11 is electrically connected to the cascade output terminal Cout, the gate of the eleventh transistor T11 is electrically connected to the pull-up node PU, the first electrode plate of the third capacitor C3 is electrically connected to the pull-up node PU, and the second electrode plate of the third capacitor C3 is electrically connected to the cascade output terminal Cout.

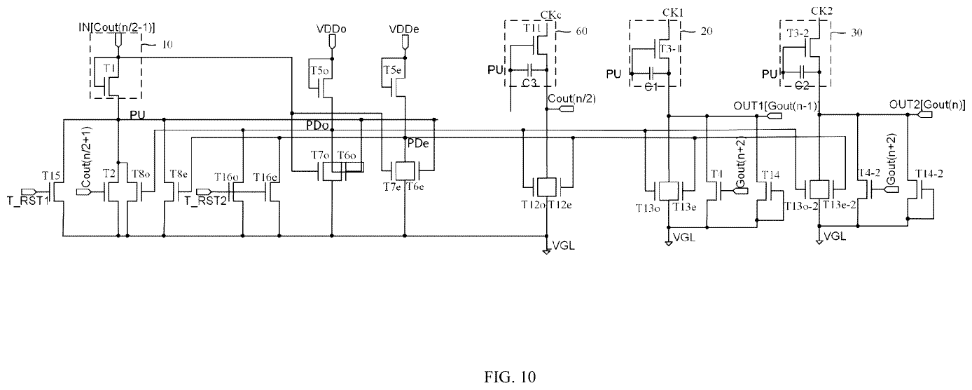

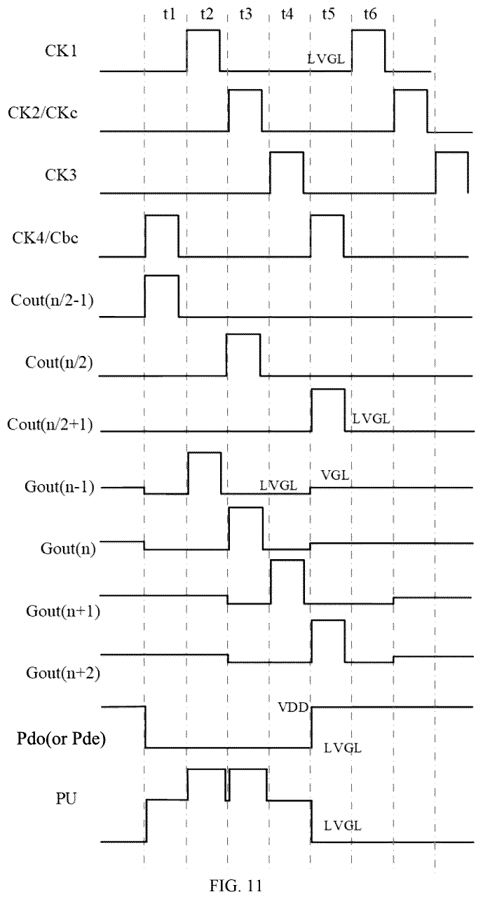

FIG. 10 is a circuit schematic diagram of another shift register according to an embodiment of the present disclosure, and FIG. 11 is a signal timing diagram of the shift register shown in FIG. 10. The working process of the shift register provided in the embodiment of the present disclosure will be described below with reference to FIG. 10 and FIG. 11. Among them, Gout (n−1) refers to the output terminal electrically connected to the (n−1)-th sub-pixel row, Gout (n) refers to the output terminal electrically connected to the n-th sub-pixel row, Gout (n+1) refers to the output terminal electrically connected to the (n+1)-th sub-pixel row, and the signal of the second clock signal terminal CK2 is the same as that of the cascade signal terminal CKc. Cout (n/2) refers to the cascade output terminal Cout of the (n/2)-th shift register, Cout (n/2−1) refers to the cascade output terminal Cout of the previous-stage shift register of the (n/2)-th shift register, and Cout (n/2+1) refers to the cascade output terminal Cout of the next-stage shift register of the (n/2)-th shift register. CK3 is the timing signal of the first clock signal terminal CK1 in the (n/2)-th shift register, and CK4 is the timing signal of the second clock signal terminal CK2 in the (n/2)-th shift register. CBc refers to the timing signal of the cascade signal terminal CKc of the next-stage shift register of the (n/2)-th shift register. CKc refers to the timing signal of the cascade signal terminal CKc of the (n/2)-th shift register.

As shown in FIG. 10 and FIG. 11:

At the stage t1, if the signal of the input terminal IN is at a high level, and the transistors T1, T7o, and T7e are conductive, then the pull-up node PU is at the high level, and the transistors T3-1, T3-2, and T11 are conductive. VDDo (or VDDe) is at the high level, and the transistor T5o (or T5e) is conductive. By setting the channel width-to-length ratio of T5/T6 such that the Pdo (or PDe) node is at a low level, the transistors T8o (or T8e), T13o, T13e, T13o-2, and T13e-2 are cut off. If Cout (n/2+1) and Gout (n+2) are at the low level, the transistors T2, T4, and T4-2 are cut off. CKc, CK1, and CK2 are at the low level, so the outputs Cout (n/2), Gout (n−1), and Gout (n) are at the low level.

At the stage t2, Cout (n/2−1) becomes the low level, the transistors T1, T7o, and T7e are cut off, and the pull-up node PU still at the high level, while the transistors T3-1, T3-2, and T11 are still conductive. If the pull-down nodes (PDo, Pde) are still at the low level, the transistors T8o (or T8e). T13o, T13e, T13o-2, and T13e-2 are still cut off. If Cout (n/2+1) and Gout (n+2) are still at the low level, the transistors T2, T4, and T4-2 are still cut off. CK1 becomes the high level, so the output Gout (n−1) becomes the high level.

At the stage t3, CK1 becomes the low level, so the output Gout (n−1) becomes the low level. And CKc and CK2 become the high level, so the outputs Cout (n/2) and Gout (n) become the high level. The status of other nodes is the same as the stage t2.

At the stage t4, CKc and CK2 become the low level, so the outputs Cout (n/2) and Gout (n) become the low level. The status of other nodes is the same as the stage t2.

At the stage t5, if Cout (n/2+1) and Gout (n+2) become the high level, the transistors T2. T4, and T4-2 are conductive. The pull-up node PU becomes the low level, and the transistors T3-1, T3-2, T11, T6o, and T6e are cut off. If T5o (or T5e) is conductive, Pdo (or Pde) becomes the high level, and the transistors T8o (or T8e), T13o (or T13e), and T13o-2 (or T13e-2) are conductive. The output remains at the low level.

In the stage t6 and subsequent stages, as long as Cout (n/2−1) remains the low level, regardless of how CKc, CK1, and CK2 change, the pull-up node PU remains the low level and the pull-down nodes (PDo, Pde) remain the high level, and the output remains the low level.

After the stage t5 and the stage t6, the outputs Cout (n/2), Gout (n−1), and Gout (n) remain the low level until Cout (n/2−1) starts the shift register again.

Continuing to refer to FIG. 4 and FIG. 10, since the voltage between the two electrode plates of the capacitor cannot suddenly change, when the signal of the first output terminal OUT1 is the high-level signal, the level at the pull-up node PU will also increase with the action of the first capacitor C1. When the level of the pull-up node PU increases under the action of the first capacitor C1, it will cause an increase in the power consumption of the shift register. For example, when the level of the pull-up node PU increases, the opening degrees of the transistors T6o and T6e increase, resulting in an increase in the leakage current through the transistors T6o and T6e, which increases the power consumption of the shift register.

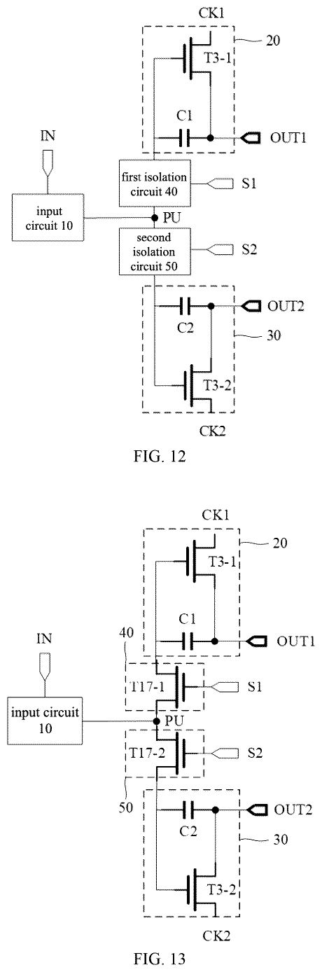

FIG. 12 is a block diagram of a partial structure of another shift register according to an embodiment of the present disclosure. As shown in FIG. 12, the shift register further includes a first isolation circuit 40, the first isolation circuit 40 is electrically connected between the pull-up node PU and the first output circuit 20, the first isolation circuit 40 is electrically connected to a first isolation control terminal S1.

For example, the first isolation circuit 40 is electrically connected to the first electrode plate of the first capacitor C1.

The first isolation circuit 40 is configured to disconnect an electrical connection between the pull-up node PU and the first output circuit 20 under the control of the signal of the first isolation control terminal S1. For example, when the first isolation control terminal S1 is at the high-level signal, the first isolation circuit 40 disconnects the electrical connection between the pull-up node PU and the first electrode plate of the first capacitor C1.

In some embodiments, the first isolation circuit 40 is configured to disconnect the electrical connection between the pull-up node PU and the first output circuit 20 when the first output terminal OUT1 is at the high-level signal.

In this way, when the signal of the first output terminal OUT1 is the high-level signal, the first isolation circuit 40 can disconnect the electrical connection between the pull-up node PU and the first electrode plate of the first capacitor C1, preventing the level of the pull-up node PU from increasing under the action of the first capacitor C1 and reducing the power consumption of the shift register.

For example, the first clock signal terminal CK1 is electrically connected to the first isolation control terminal S1. This can make the first clock signal terminal CK1 and the first isolation control terminal S1 both at the high-level signals, and reduce the number of clock signal lines in the non-active area, thereby reducing the width of the bezel.

FIG. 13 is a schematic diagram of the partial structure of another shift register according to an embodiment of the present disclosure. As shown in FIG. 13, the first isolation circuit 40 may include a first isolation transistor T17-1, a first electrode of the first isolation transistor T17-1 is electrically connected to the pull-up node PU, a second electrode of the first isolation transistor T17-1 is electrically connected to the first output circuit 20, and a gate of the first isolation transistor T17-1 is electrically connected to the first isolation control terminal S1.

For example, the second electrode of the first isolation transistor T17-1 is electrically connected to the first electrode plate of the first capacitor C1.

Continuing to refer to FIG. 12 and FIG. 13, the shift register may also include a second isolation circuit 50, the second isolation circuit 50 is electrically connected between the pull-up node PU and the second output circuit 30, the second isolation circuit 50 is electrically connected to a second isolation control terminal S2.

For example, the second isolation circuit 50 is electrically connected to the first electrode plate of the second capacitor C2.

The second isolation circuit 50 is configured to disconnect an electrical connection between the pull-up node PU and the second output circuit 30 under control of a signal from the second isolation control terminal S2. For example, when the second isolation control terminal S2 is at the high-level signal, the second isolation circuit 50 disconnects the electrical connection between the pull-up node PU and the first electrode plate of the second capacitor C2.

In some embodiments, the second isolation circuit 50 is configured to disconnect an electrical connection between the pull-up node PU and the second output circuit 30 when the second output terminal OUT2 is at the high-level signal.

In this way, when the signal of the second output terminal OUT2 is the high-level signal, the second isolation circuit 50 can disconnect the electrical connection between the pull-up node PU and the first electrode plate of the second capacitor C2, preventing the level of the pull-up node PU from increasing under the action of the second capacitor C2 and reducing the power consumption of the shift register.

For example, the second clock signal terminal CK2 is electrically connected to the second isolation control terminal S2. This can make the second clock signal terminal CK2 and the second isolation control terminal S2 both at the high-level signals, and reduce the number of the clock signal lines in the non-active area, thereby reducing the width of the bezel.

As shown in FIG. 13, the second isolation circuit 50 may include a second isolation transistor T17-2. The first electrode of the second isolation transistor T17-2 is electrically connected to the pull-up node PU, the second electrode of the second isolation transistor T17-2 is electrically connected to the second output circuit 30, and the gate of the second isolation transistor T17-2 is electrically connected to the second isolation control terminal S2.

For example, the second electrode of the second isolation transistor T17-2 is electrically connected to the first electrode plate of the second capacitor C2.

In addition, when the shift register includes the first isolation circuit 40, the second isolation circuit 50, and the cascade circuit 60 at the same time, it can improve the display uniformity of two adjacent sub-pixel rows. Specifically, when the cascade signal terminal CKc is electrically connected to the second clock signal terminal CK2, both the cascade signal terminal CKc and the second clock signal terminal CK2 are at the high level. At this time, the level of the pull-up node PU increases under the joint action of the cascade output terminal Cout and the second output terminal OUT2. However, when the first clock signal terminal CK1 is at the high level, the level of the pull-up node PU only increases under the action of the first output terminal OUT1, resulting in inconsistent levels of the pull-up node PU at two time periods, leading to poor display uniformity between two adjacent sub-pixel rows. After simultaneously setting up the first isolation circuit 40 and the second isolation circuit 50, the level difference of the pull-up node PU is eliminated, and the display uniformity is improved.

The first isolation control terminal S1 and the second isolation control terminal S2 can be electrically connected. For example, the first isolation control terminal S1 and the second isolation control terminal S2 are electrically connected to the same clock signal line, which can reduce the number of the clock signal lines and further reduce the area of the non-active area, achieving a narrow bezel.

Among them, the clock signal line electrically connected to the first isolation control terminal S1 and the second isolation control terminal S2 may be a separately set clock signal line. The signal in this separately set clock signal line satisfies that when the signal of the first output terminal OUT1 is the high-level signal, the signal in the clock signal line is also the high-level signal, and when the signal of the second output terminal OUT2 is the high-level signal, the signal in the clock signal line is also the high-level signal.

Certainly, the first isolation control terminal S1 and the second isolation control terminal S2 may not be connected, and the signal of the first isolation control terminal S1 and the signal of the second isolation control terminal S2 may be the same or different.

The clock signal line electrically connected to the first isolation control terminal S1 or the second isolation control terminal S2 can also be a clock signal line electrically connected to the first clock signal terminal CK1 or the second clock signal terminal CK2 of another shift register. This can reduce the member of the clock signal lines in the non-active area, thereby reducing the bezel width of the display panel.

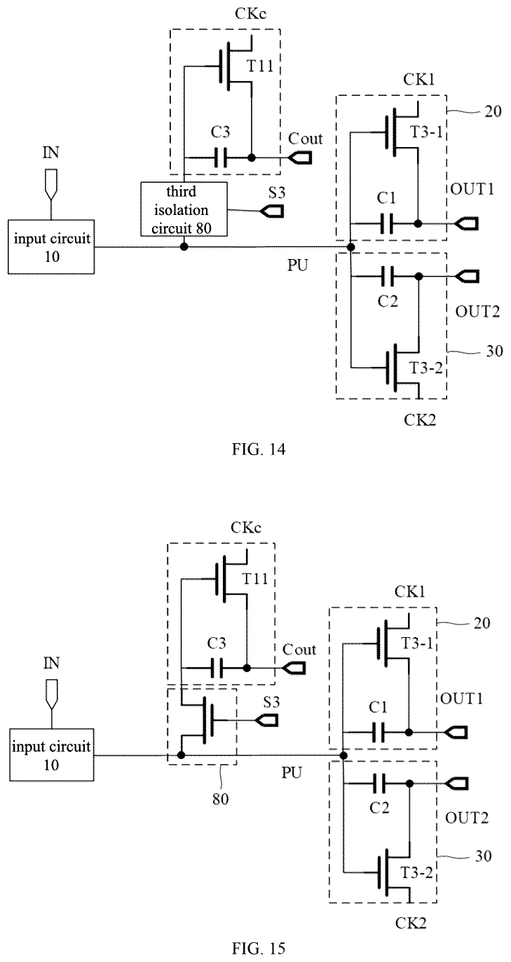

FIG. 14 is a schematic structural diagram of another shift register according to an embodiment of the present disclosure. As shown in FIG. 14, when the shift register includes a cascade circuit 60, the shift register also includes a third isolation circuit 80, the third isolation circuit 80 is electrically connected between the pull-up node PU and the cascade circuit 60, and the third isolation circuit 80 is electrically connected to the fifth clock signal terminal.

For example, the third isolation circuit 80 is electrically connected to the first electrode plate of the third capacitor C3.

The third isolation circuit 80 is configured to disconnect the electrical connection between the pull-up node PU and the cascade circuit 60 under the control of the signal of the third isolation control terminal S3. For example, when the third isolation control terminal S3 is at the high-level signal, the third isolation circuit 80 disconnects the electrical connection between the pull-up node PU and the first electrode plate of the third capacitor C3.

In some embodiments, the third isolation circuit 80 is configured to disconnect the electrical connection between the pull-up node PU and the cascade circuit 60 when the cascade output terminal Cout is at the high-level signal.

In this way, when the signal of the cascade output terminal Cout is the high-level signal, the third isolation circuit 80 can disconnect the electrical connection between the pull-up node PU and the first electrode plate of the third capacitor C3, preventing the level of the pull-up node PU from increasing under the action of the third capacitor C3 and reducing the power consumption of the shift register.

For example, the first clock signal terminal CK1 or the second clock signal terminal CK2 is electrically connected to the third isolation control terminal S3. This can reduce the number of the clock signal lines in the non-active area, thereby reducing the width of the bezel.

The third isolation control terminal S3 can be electrically connected to the first isolation control terminal S1 and the second isolation control terminal S2, thus reducing the number of the clock signal lines in the non-active area, thereby reducing the width of the bezel.

FIG. 15 is a schematic diagram of the partial structure of another shift register according to an embodiment of the present disclosure. As shown in FIG. 15, the third isolation circuit 80 may include a third isolation transistor T17-3, the first electrode of the third isolation transistor T17-3 is electrically connected to the pull-up node PU, the second electrode of the third isolation transistor T17-3 is electrically connected to the cascade circuit 60, and the gate of the third isolation transistor T17-3 is electrically connected to the third isolation control terminal S3.

For example, the second electrode of the third isolation transistor T17-3 is electrically connected to the first electrode plate of the third capacitor C3.

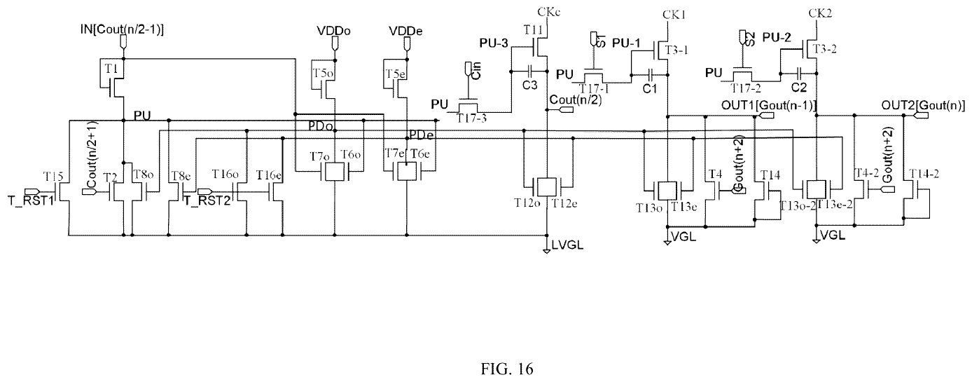

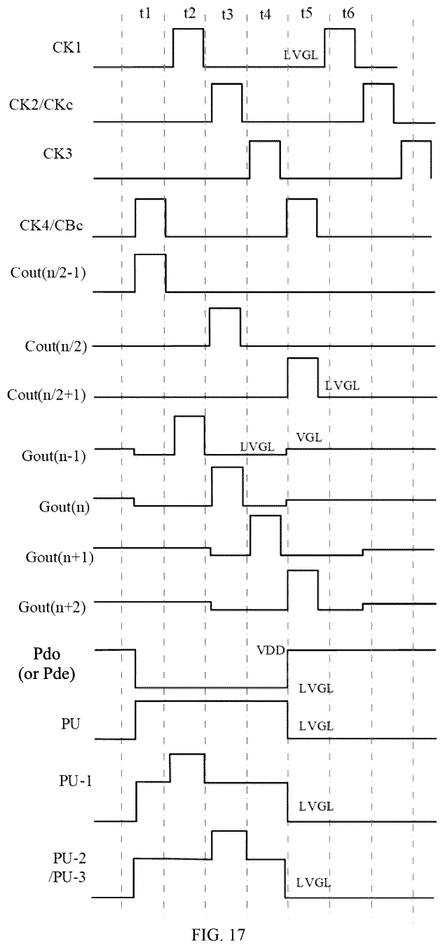

FIG. 16 is a circuit schematic diagram of another shift register according to an embodiment of the present disclosure, and FIG. 17 is a timing signal diagram of the shift register shown in FIG. 16. As shown in FIG. 16 and FIG. 17, by simultaneously setting the first isolation circuit 40, the second isolation circuit 50, and the third isolation circuit 80, the level of the pull-up node PU will not be raised, which is beneficial for reducing the power consumption of the shift register and improving the display uniformity of two adjacent sub-pixel rows.

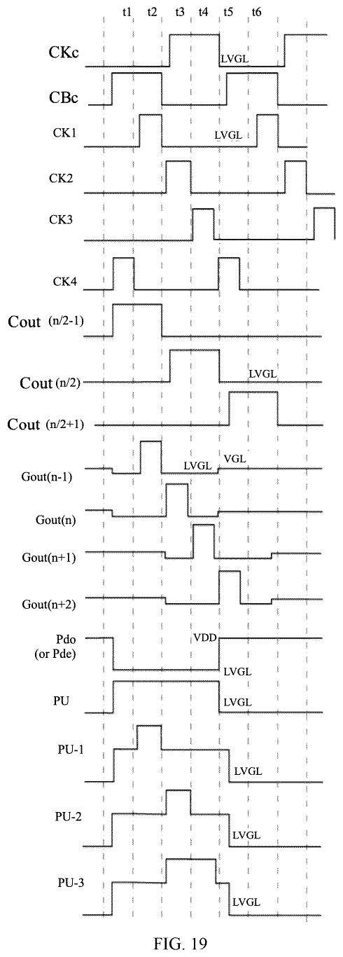

FIG. 19 is a timing signal diagram of the shift register shown in FIG. 16. As shown in FIG. 19, the first isolation control terminal S1, the second isolation control terminal S2, and the third isolation control terminal S3 of the n-th shift register can be electrically connected to a separately set clock signal line. At this time, the signal inside the clock signal line is shown as CKc in FIG. 19. The first isolation control terminal S1, the second isolation control terminal S2, and the third isolation control terminal S3 of the (n+1)-th shift register can be electrically connected to the separately set clock signal line. At this time, the signal inside the clock signal line is shown as CBc in FIG. 19.

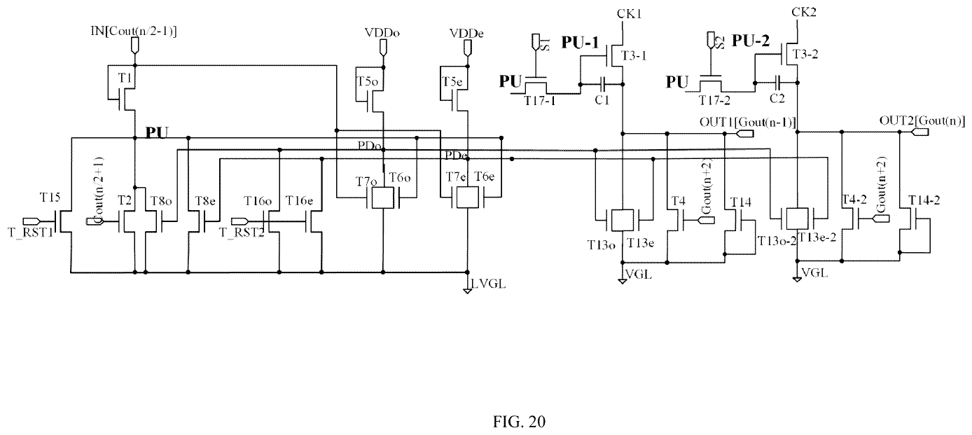

FIG. 20 shows the circuit schematic diagram of another shift register according to an embodiment of the present disclosure. As shown in FIG. 20, when the shift register is not provided with the cascade circuit 60, the first isolation circuit 40 and the second isolation circuit 50 can also be set at this time.

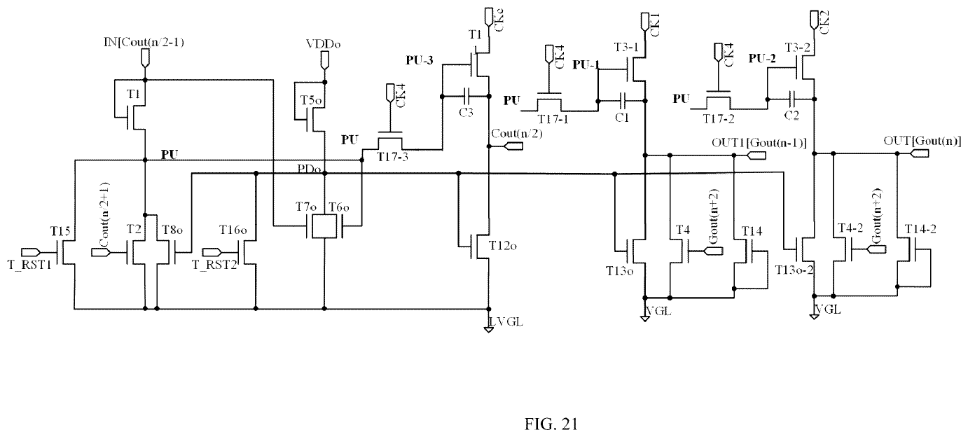

FIG. 21 is a circuit schematic diagram of another shift register according to an embodiment of the present disclosure. Compared to the shift register shown in FIG. 16, the shift register shown in FIG. 21 deletes the transistors T5e, T6e, T7e, T8e, T12e, T13e, T13e-2, and T16e. This can reduce the number of the transistors in the shift register, thereby reducing the area of the non-active area NA. At this point, when the transistor is under stress-99%, the threshold voltage Vth shift of the transistor still does not exceed the design threshold (such as 0.1-3V, etc.).

When the threshold voltage Vth of the transistor satisfies Vth<0V, the voltage Vgs between the gate and the source of the transistor satisfies Vgs=0V. Id is large, when severe, it can easily cause the shift register to fail to shift normally, and when mild, the leakage of the shift register is large, resulting in increased power consumption.

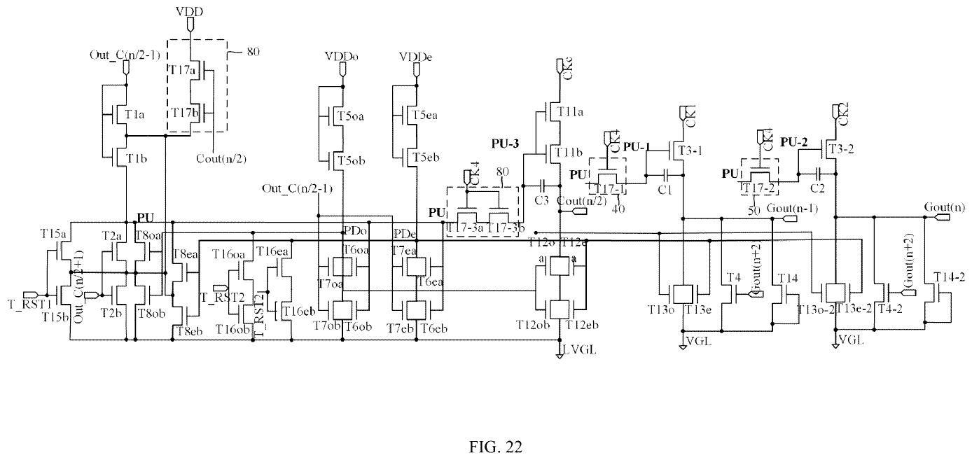

FIG. 22 is a circuit schematic diagram of another shift register according to an embodiment of the present disclosure. As shown in FIG. 22, in order to improve the above-mentioned defects, at least some transistors in the shift register adopt a double gate structure, that is, two transistors are connected in series, and the gates of the two transistors connected in series are electrically connected. This can reduce node leakage, thereby increasing the negative bias margin of the threshold voltage Vth and reducing the power consumption.

For example, the transistors T1, T2, T8o, T15, and T17-3 in FIG. 16 are replaced with the double gate structure. Due to the high level of the pull-up node PU at the output stage, replacing the transistors T1, T2, T8o, T15, and T17-3 with the double gate structure can reduce leakage.

It should be noted that in FIG. 16, except for T1, T2, T8o, T15, and T17-3, some or all of the other transistors can also be replaced with the double gate structure.

The shift register shown in FIG. 22 includes a plurality of output terminals, allowing one shift register to provide scanning signals to a plurality of sub-pixel rows, reducing the number of the shift registers, and increasing the deployable space of each shift register without changing the area of the non-active area. As a result, some or all transistors in the shift register can be replaced with the double gate structure, reducing the power consumption of the display panel and improving the reliability of the display panel. That is, without changing the area of the non-active area NA, the power consumption of the display panel is reduced and the reliability of the display panel is improved.

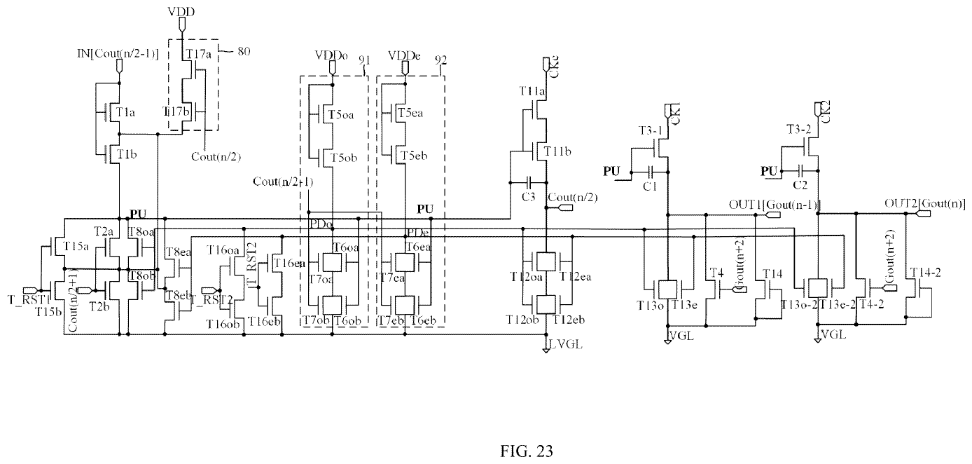

FIG. 23 is a circuit schematic diagram of another shift register according to an embodiment of the present disclosure. The difference between the shift register shown in FIG. 23 and the shift register shown in FIG. 22 is that the first isolation circuit 40, the second isolation circuit 50, and the third isolation circuit 80 are not provided in the shift register shown in FIG. 23. When the first output terminal OUT1, the second output terminal OUT2, or the cascade output terminal Cout outputs the high-level signal, the level of the pull-up node PU will increase under the action of the capacitor, resulting in an increase in leakage.

In view of this, referring to FIG. 23, the input circuit 10 includes a first input transistor T1a and a second input transistor T1b. The first electrode of the first input transistor T1a is electrically connected to the input terminal IN, the second electrode of the first input transistor T1a is electrically connected to the first electrode of the second input transistor T1b, the second electrode of the second input transistor T1b is electrically connected to the pull-up node PU, and the gates of the first input transistor T1a and the second input transistor T1b are electrically connected to the input terminal IN. The shift register also includes a leakage-prevention circuit 80, the leakage-prevention circuit 80 is electrically connected to the first voltage terminal VDD, the leakage-prevention control terminal, and the second electrode of the first input transistor T1a. The leakage-prevention circuit 80 is configured to write the signal of the first voltage terminal VDD to the second electrode of the first input transistor T1a under the control of the signal of the leakage-prevention control terminal.

For example, referring to FIG. 23, the leakage-prevention circuit 80 includes transistors T17a and T17b. The transistors T17a and T17b are the double gate structure, with their gates electrically connected to the cascade output terminals Cout or Gout (n−1) of the (n/2)-th shift register or the pull-up node PU, one electrode thereof is electrically connected to the first voltage terminal VDD, and the other electrode thereof is connected between the transistors T1a and T1b. When the level of the pull-up node PU increases under the action of the capacitor, the voltage difference between the pull-up node PU and the intermediate node of the double gate structure decreases, reducing the leakage voltage drop of the pull-up node PU, especially when the threshold voltage Vth satisfies Vth<0.

Certainly, the other electrode of the transistor T17b can also be connected to one or more positions between T2a and T2b, between T8a and T8ob, between T8ea and T8eb, or between T15a and T15b.

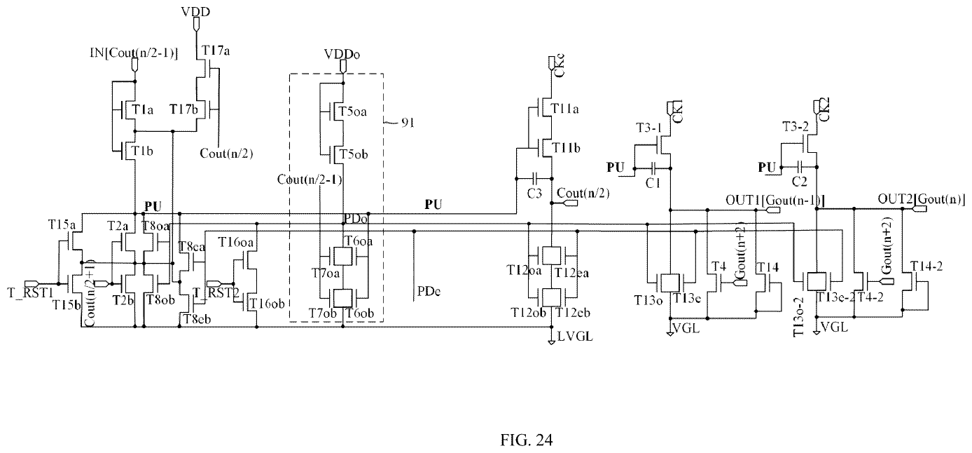

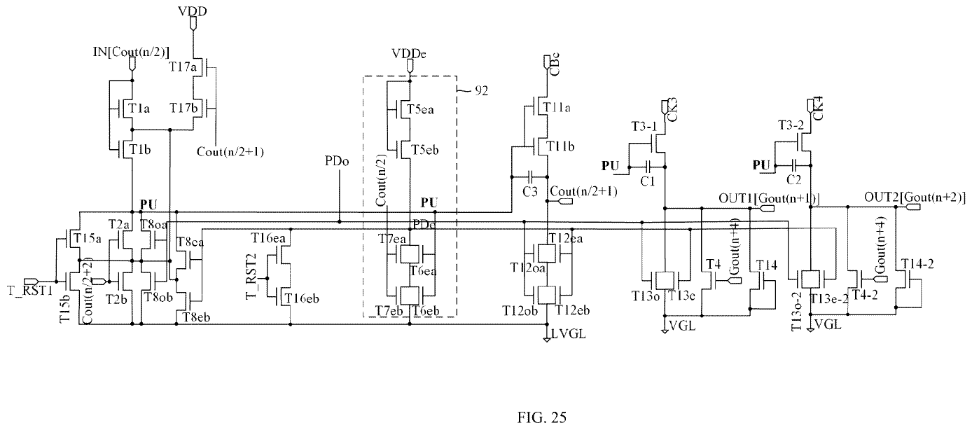

FIG. 24 is a circuit schematic diagram of a first shift register according to an embodiment of the present disclosure, and FIG. 25 is a circuit schematic diagram of a second shift register according to an embodiment of the present disclosure. Among them, the shift registers shown in FIG. 24 and FIG. 25 are two cascaded shift registers.

Compared with the shift register shown in FIG. 23, the first shift register shown in FIG. 24 deletes the second noise reduction circuit 92, that is, the transistors T5ea, T8eb, T7ea, T7eb, T6ea, and T6eb are deleted, reducing the number of the transistors in the shift register and thus reducing the area of the non-active area. Compared with the shift register shown in FIG. 23, the second shift register shown in FIG. 25 deletes the first noise reduction circuit 91, that is, the transistors T5oa, T5ob, T7oa, T7ob, T6oa, and T6ob are deleted, reducing the number of the transistors in the shift register and thus reducing the area of the non-active area.

Among them, the pull-down node PDe of the first shift register in FIG. 24 is electrically connected to the pull-down node Pde of the second shift register in FIG. 25, and the pull-down node PDo of the second shift register in FIG. 25 is electrically connected to the pull-down node Pdo of the first shift register in FIG. 24.

The shift register shown in FIG. 24 and the shift register shown in FIG. 25 share a first noise reduction circuit and a second noise reduction circuit, reducing the number of the first noise reduction circuit and the second noise reduction circuit in the scanning driver circuit, and thus reducing the area of the non-active area.

The above is only a specific implementation of the present disclosure, but the scope of protection of the present disclosure is not limited to this. Any skilled person familiar with this technical field can easily think of changes or replacements within the technical scope disclosed in the present disclosure, which should be included in the scope of protection of the present disclosure. Therefore, the scope of protection of the present disclosure should be based on the scope of protection of the claims.

1. A shift register, comprising:
an input circuit, wherein the input circuit is electrically connected to an input terminal and a pull-up node, and the input circuit is configured to write a signal from the input terminal to the pull-up node;
a first output circuit, wherein the first output circuit is electrically connected to the pull-up node, a first clock signal terminal and a first output terminal, and the first output circuit is configured to write a signal from the first clock signal terminal to the first output terminal under control of a signal at the pull-up node;
a second output circuit, wherein the second output circuit is electrically connected to the pull-up node, a second clock signal terminal and a second output terminal, and the second output circuit is configured to write a signal from the second clock signal terminal to the second output terminal under the control of the signal at the pull-up node.

2. The shift register according to claim 1, wherein the shift register further comprises:
a first isolation circuit, wherein the first isolation circuit is electrically connected between the pull-up node and the first output circuit, the first isolation circuit is electrically connected to a first isolation control terminal, and the first isolation circuit is configured to disconnect an electrical connection between the pull-up node and the first output circuit under control of a signal from the first isolation control terminal.

3. The shift register according to claim 2, wherein the shift register further comprises:
a second isolation circuit, wherein the second isolation circuit is electrically connected between the pull-up node and the second output circuit, the second isolation circuit is electrically connected to a second isolation control terminal, and the second isolation circuit is configured to disconnect an electrical connection between the pull-up node and the second output circuit under control of a signal from the second isolation control terminal.

4. The shift register according to claim 3, wherein the first isolation control terminal is electrically connected to the second isolation control terminal.

5. The shift register according to claim 3, wherein the first isolation circuit is configured to disconnect the electrical connection between the pull-up node and the first output circuit when the first output terminal is at a high-level signal; and/or, the second isolation circuit is configured to disconnect the electrical connection between the pull-up node and the second output circuit when the second output terminal is at the high-level signal.

6. The shift register according to claim 3, wherein the first isolation circuit comprises a first isolation transistor, a first electrode of the first isolation transistor is electrically connected to the pull-up node, a second electrode of the first isolation transistor is electrically connected to the first output circuit, and a gate of the first isolation transistor is electrically connected to the first isolation control terminal; and/or.
the second isolation circuit comprises a second isolation transistor, a first electrode of the second isolation transistor is electrically connected to the pull-up node, a second electrode of the second isolation transistor is electrically connected to the second output circuit, and a gate of the second isolation transistor is electrically connected to the second isolation control terminal.

7. The shift register according to claim 1, wherein the shift register further comprises:
a cascade circuit, wherein the cascade circuit is electrically connected to a cascade signal terminal, the pull-up node and a cascade output terminal, and the cascade circuit is configured to write a signal from the cascade signal terminal to the cascade output terminal under the control of the signal at the pull-up node.

8. The shift register according to claim 7, wherein the shift register further comprises:
a third isolation circuit, wherein the third isolation circuit is electrically connected between the pull-up node and the cascade circuit, the third isolation circuit is electrically connected to a third isolation control terminal, and the third isolation circuit is configured to disconnect an electrical connection between the pull-up node and the cascade circuit under control of a signal from the third isolation control terminal.

9. The shift register according to claim 8, wherein the third isolation control terminal is electrically connected to a first isolation control terminal and a second isolation control terminal.

10. The shift register according to claim 8, wherein the third isolation circuit comprises a third isolation transistor, a first electrode of the third isolation transistor is electrically connected to the pull-up node, a second electrode of the third isolation transistor is electrically connected to the cascade circuit, and a gate of the third isolation transistor is electrically connected to the third isolation control terminal.

11. The shift register according to claim 1, wherein at least a portion of transistors in the shift register are double gate structures.

12. The shift register according to claim 11, wherein the input circuit comprises a first input transistor and a second input transistor, a first electrode of the first input transistor is electrically connected to the input terminal, a second electrode of the first input transistor is electrically connected to a first electrode of the second input transistor, a second electrode of the second input transistor is electrically connected to the pull-up node, and gates of the first input transistor and the second input transistor is electrically connected to the input terminal;
the shift register further comprises a leakage-prevention circuit, the leakage-prevention circuit is electrically connected to a first voltage terminal, a leakage-prevention control terminal and the second electrode of the first input transistor, and the leakage-prevention circuit is configured to write a signal from the first voltage terminal to the second electrode of the first input transistor under control of a signal from the leakage-prevention control terminal.

13. The shift register according to claim 1, wherein the shift register further comprises a reset circuit, the reset circuit is electrically connected to a first pull-down node, a second pull-down node, the first output terminal, the second output terminal and a second voltage terminal, and the reset circuit is configured to write a signal from the second voltage terminal to the first output terminal or the second output terminal under control of a signal at the first pull-down node or the second pull-down node.

14. A scanning driver circuit, wherein the scanning driver circuit comprises a plurality of shift registers according to claim 1, and the plurality of shift registers are cascaded.

15. The scanning driver circuit according to claim 14, wherein the plurality of shift registers comprise a first shift register and a second shift register, the first shift register and the second shift register are cascaded, a first pull-down node of the first shift register is electrically connected to a first pull-down node of the second shift register, and a second pull-down node of the first shift register is electrically connected to a second pull-down node of the second shift register; and
the first shift register further comprises a first noise-reduction circuit, the first noise-reduction circuit is electrically connected to the first pull-down node, and the second shift register further comprises a second noise-reduction circuit, the second noise-reduction circuit is electrically connected to the second pull-down node.

16. A display panel, wherein the display panel comprises the shift register according to claim 1.

17. The display panel according to claim 16, wherein the display panel further a plurality of sub-pixel rows, the plurality of sub-pixel rows include a first sub-pixel row and a second sub-pixel row that are adjacent, the first output terminal is electrically connected to the first sub-pixel row, and the second output terminal is electrically connected to the second sub-pixel row.

18. A display panel, wherein the display panel comprises the scanning driver circuit according to claim 14.

19. The display panel according to claim 18, wherein the display panel further comprises a plurality of gate lines, a plurality of data lines, and a plurality of sub-pixels;
the display panel comprises an active area and a non-active area electrically connected to the active area; and
the plurality of sub-pixels, the plurality of gate lines, and the plurality of data lines are located within the active area, and the scanning driver circuit is located within the non-active area.

20. The display panel according to claim 19, wherein first output terminals and second output terminals of the plurality of shift registers are electrically connected to the plurality of gate lines, respectively.
